(19) United States
(12) Patent Application Publication
(10) Pub. No.: US 2026/0214989 A1
(43) Pub. Date: Jul. 23, 2026

(54) ARRAY SUBSTRATE, DISPLAY PANEL, AND DISPLAY APPARATUS

(71) Applicants: Beijing BOE Optoelectronics Technology Co., Ltd., Beijing (CN); BOE Technology Group Co., Ltd., Beijing (CN)

(72) Inventors: Ruomei BIAN, Beijing (CN); Peipei WANG, Beijing (CN); Wulin ZHANG, Beijing (CN); Honggui JIN, Beijing (CN); Zhilong DUAN, Beijing (CN); Pingyuan SUN, Beijing (CN); Yang LIU, Beijing (CN); Yong ZHANG, Beijing (CN)

(21) Appl. No.: 19/145,921

(22) PCT Filed: Jun. 12, 2024
(86) PCT No.: PCT/CN2024/098779

§ 371 Date: Jul. 5, 2025

(30) Foreign Application Priority Data
Jul. 4, 2023 (CN) 202310813553.8

(51) Int. Cl. H10D 86/40; H10D 86/60

(52) U.S. Cl. CPC H10D 86/443; H10D 86/60

(57) ABSTRACT

An array substrate, a display panel, and a display apparatus are disclosed. The array substrate includes: a control chip region, located in a non-display region and used for being electrically connected with a control chip; a bonding region, located in the non-display region and at a side of the control chip region and used for being electrically connected with a circuit board; a first electrostatic protection pad, located in the non-display region, and the first electrostatic protection pad and the bonding region being located on different sides of the control chip region; and a ground wire, located in the non-display region and including a first ground wire part. One end of the first electrostatic protection pad is electrically connected with a terminal included in the bonding region through the first ground wire part surrounding the display region.

### CROSS-REFERENCE TO RELATED APPLICATIONS

This application is a National Stage of International Application No. PCT/CN2024/098779, filed on Jun. 12, 2024, which claims priority to Chinese Patent Application No. 202310813553.8, filed with the China National Intellectual Property Administration on Jul. 4, 2023, and entitled “Array Substrate, Display Panel, and Display Apparatus”, the content of which is hereby incorporated by reference in its entirety.

### TECHNICAL FIELD

The present disclosure relates to the technical field of semiconductor, and in particular to an array substrate, a display panel, and a display apparatus.

### BACKGROUND

In recent years, the demand for array substrate design has been constantly changing. In order to meet narrow bezel requirements of products, design optimization has been carried out based on Chip On Glass (COG) design, and Chip On Film Like (COFL) design has been proposed, as shown in a-c in FIG. 1. For the scheme of placing the chip on a glass substrate, in order to further achieve a narrow bezel, the FPC can be split and placed on both sides of the IC.

### SUMMARY

The present disclosure provides an array substrate, a display panel, and a display apparatus, to alleviate the problem that an array substrate in related art is easily damaged by static electricity when a bonding region at a side of the array substrate is removed.

Embodiments of the present disclosure provide an array substrate, having a display region and a non-display region at a periphery of the display region, where the array substrate includes:
a control chip region, located in the non-display region and used for being electrically connected with a control chip;
a bonding region, located in the non-display region and at a side of the control chip region and used for being electrically connected with a circuit board;
a first electrostatic protection pad in the non-display region, where the first electrostatic protection pad and the bonding region are at different sides of the control chip region; and
a ground wire, located in the non-display region and including a first ground wire part, where one end of the first electrostatic protection pad is electrically connected with a terminal included in the bonding region through the first ground wire part surrounding the display region.

In a possible embodiment, the ground wire further includes a second ground wire part; the other end of the first electrostatic protection pad is electrically connected with a terminal included in the control chip region through the second ground wire part.

In a possible embodiment, the array substrate further includes a second electrostatic protection pad; the ground wire further includes a third ground wire part;
the second electrostatic protection pad is electrically connected with a terminal included in the bonding region through the third ground wire part.

In a possible embodiment, the ground wire further includes a fourth ground wire part; the control chip region is electrically connected with the bonding region through the fourth ground wire part.

In a possible embodiment, the array substrate further includes a fifth ground wire part; the fifth ground wire part is at a side of the control chip region away from the display region, one end of the fifth ground wire part is electrically connected with a terminal included at one end of the control chip region, and the other end of the fifth ground wire part is electrically connected with a terminal included at the other end of the control chip region.

In a possible embodiment, a length of the fifth ground wire part is substantially equal to a length of the control chip region.

In a possible embodiment, at least a part of at least one of the first ground wire part, a second ground wire part, a third ground wire part, a fourth ground wire part, or a fifth ground wire part is arc-shaped.

In a possible embodiment, the control chip region extends along a first direction, and has a first symmetry axis perpendicular to the first direction;
the first electrostatic protection pad and a second electrostatic protection pad are symmetrical with respect to the first symmetry axis.

In a possible embodiment, an outer contour of the array substrate is circular, elliptical, hexagonal or octagonal.

In a possible embodiment, the first electrostatic protection pad and a second electrostatic protection pad are distributed in a splayed shape.

Embodiments of the present disclosure provide a display panel, including the array substrate according to embodiments of the present disclosure, an opposite substrate opposite to the array substrate, the control chip in the control chip region, and the circuit board in the bonding region.

In a possible embodiment, the display panel further includes: a conductive adhesive; part of the conductive adhesive covers a peripheral part of the opposite substrate, and part of the conductive adhesive extends to the first electrostatic protection pad and/or a second electrostatic protection pad of the array substrate along a side edge of the opposite substrate.

In a possible embodiment, a conductive layer is at a side of the opposite substrate away from the array substrate, and the conductive adhesive is lapped with the conductive layer.

In a possible embodiment, the array substrate includes a first region overlapped with the opposite substrate, and a second region extending from the first region; the control chip region, the bonding region, and the ground wire are all in the second region of the array substrate.

Embodiments of the present disclosure provide a display apparatus, including the display panel according to embodiments of the present disclosure.

Embodiments of the present disclosure provide a display apparatus, including the array substrate according to embodiments of the present disclosure.

Beneficial effects of embodiments of the present disclosure are as follows: in embodiments of the present disclosure, for the first electrostatic protection pad at the side different from the bonding region, the first electrostatic protection pad is electrically connected with the terminal included in the bonding region at the other side of the control chip region through the first ground wire part surrounding the display region AA. When a circuit board at a side where the first electrostatic protection pad is located is removed, the first electrostatic protection pads on the side can still be connected with a circuit board on the other side of the control chip region, and the first electrostatic protection pad on the side can still play an electrostatic protection role. The enhancement effect of the first electrostatic protection pad on the electrostatic shielding effect is not weakened, solving the problem that the array substrate in the related art is easily damaged by static electricity when the bonding region at a side of the array substrate is removed.

### BRIEF DESCRIPTION OF FIGURES

FIG. 1 is a schematic diagram of array substrates with control chip regions at different positions;

FIG. 2 is a schematic diagram of a circular array substrate with two bonding regions at different sides of a control chip region;

FIG. 3 is a schematic diagram of an array substrate according to an embodiment of the present disclosure;

FIG. 4A is a partially enlarged schematic view of FIG. 3;

FIG. 4B is a first wiring diagram of a control chip region according to an embodiment of the present disclosure;

FIG. 4C is a second wiring diagram of a control chip region according to an embodiment of the present disclosure;

FIG. 4D is a third wiring diagram of a control chip region according to an embodiment of the present disclosure;

FIG. 4E is an enlarged schematic view at a dotted coil S2 in FIG. 4A;

FIG. 5 is a schematic diagram of a display panel according to an embodiment of the present disclosure;

FIG. 6 is a cross-sectional view of an array substrate according to an embodiment of the present disclosure.

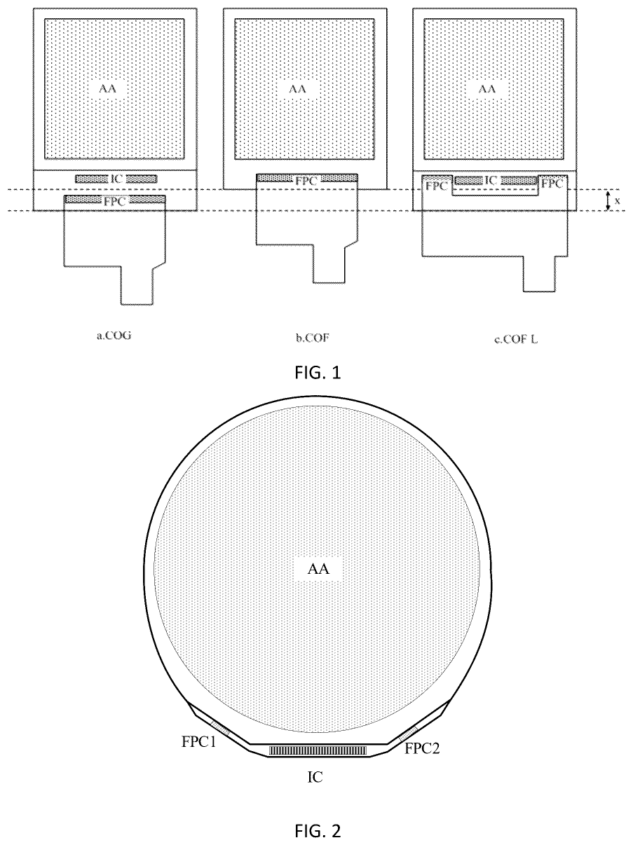

### DETAILED DESCRIPTION

For making objectives, technical solutions and advantages of embodiments of the present disclosure clearer, technical solutions of embodiments of the present disclosure will be clearly and completely described below in combination with accompanying drawings in embodiments of the present disclosure. Apparently, embodiments described are some rather than all of embodiments of the present disclosure. Based on embodiments of the present disclosure, all other embodiments obtained by those of ordinary skill in the art without making creative efforts fall within the scope of protection of the present disclosure.

Unless otherwise defined, technical or scientific terms used in the present disclosure should have ordinary meanings as understood by those of ordinary skill in the art to which the present disclosure belongs. The words “first”, “second”, etc. used in the present disclosure do not indicate any order, quantity or importance, but are only used to distinguish different components. The word “including” or “comprising”, etc. indicates that elements or objects before the word include elements or objects after the word and their equivalents, without excluding other elements or objects. The word “connection” or “link”, etc. is not limited to physical or mechanical connections, but may include electrical connections, whether direct or indirect. “Inner”, “outer”, “upper”, “lower”, etc. are only used to indicate a relative positional relationship, and when an absolute position of a described object changes, the relative positional relationship may also change accordingly.

As used herein, “approximately” or “roughly the same” includes a stated value and means within an acceptable range of deviation for a specific value as determined by those of ordinary skill in the art, taking into account measurement in question and measurement related errors (i.e., limitations of a measurement system). For example, “roughly the same” may mean that a difference relative to the stated value is within one or more standard deviations, or within a range of ±30%, 20%, 10%, or 5%.

In the drawings, thicknesses of layers, films, panels, regions, etc., are exaggerated for clarity. Exemplary embodiments are described herein with reference to cross-sectional views that are schematic illustrations of idealized embodiments. As such, deviations from the shape of the drawing will be expected as a result of, for example, manufacturing techniques and/or tolerances. Thus, embodiments described herein should not be construed as limited to the specific shapes of the regions shown herein, but include deviations in shape caused by, for example, manufacturing. For example, regions illustrated or described as flat may typically have rough and/or non-linear characteristics. Further, sharp corners illustrated may be rounded. Thus, regions shown in the drawings are schematic in nature and their shapes are not intended to illustrate precise shapes of the regions, and are not intended to limit the scope of the claims.

Detailed descriptions of known functions and known components are omitted from the present disclosure in order to keep the following description of embodiments of the present disclosure clear and concise.

In recent years, the market demand for special-shaped/circular wearable products has been increasing. In order to reduce the panel bezel, COF Like design is also used, as shown in FIG. 2. However, in the actual product production process, because the FPC1 and the FPC2 are in a “splayed shape” design, there are problems that bonding devices can not automatically correspond, and using manual bonding for corresponding processing is time-consuming, labor-intensive, and has a high defect rate. Therefore, the design cancels the FPC on one side and only uses the FPC on the other side to transmit panel function signals. This design requirement poses a challenge to the panel and has following problems: after the FPC on one side is cancelled, a ground protection structure (such as Ag glue dot) at the side cannot be connected with a ground (GND) signal terminal of the original FPC, and a peripheral GND wire at the side loses effective signal wire connection. This change causes the product to have electro-static discharge (ESD) risk.

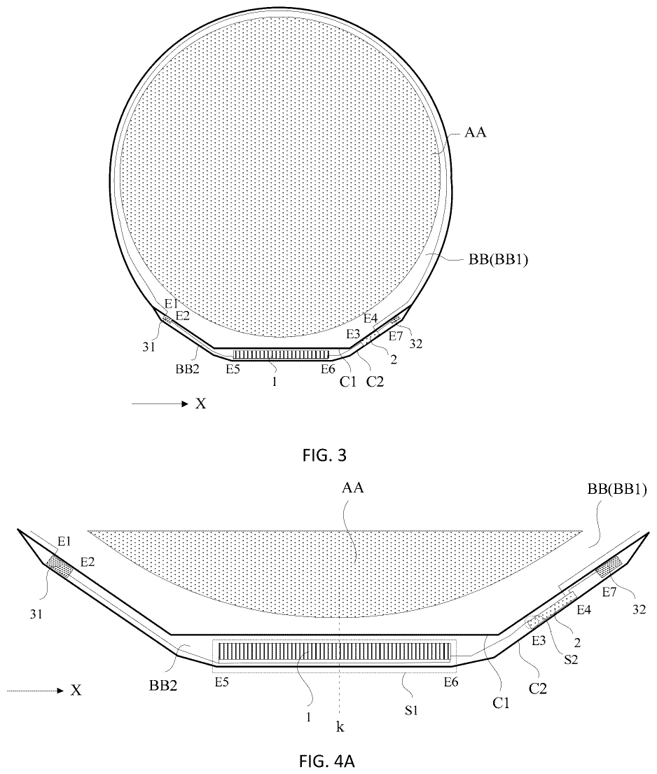

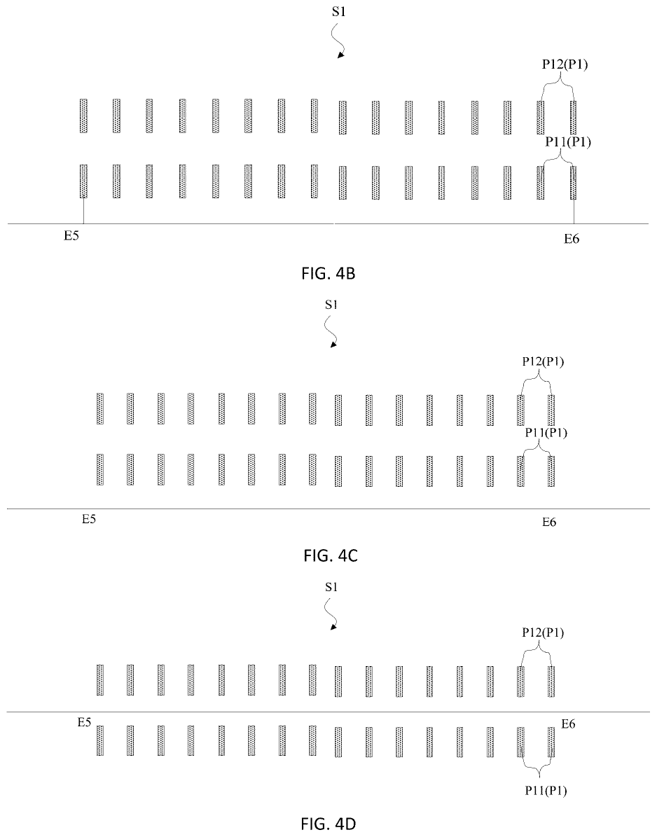

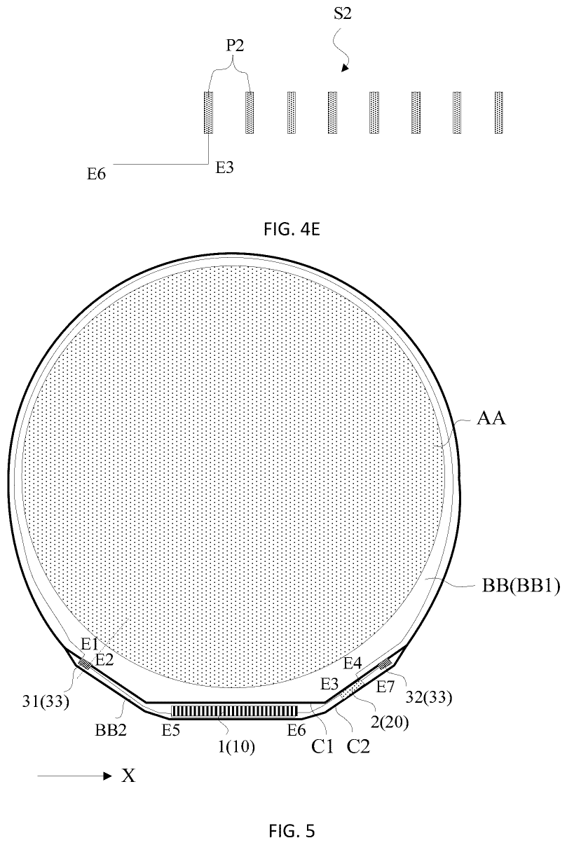

In view of this, referring to FIG. 3 and FIG. 4A, embodiments of the present disclosure provide an array substrate having a display region AA, and a non-display region BB at a periphery of the display region AA. The array substrate includes follows.

A control chip region 1 is located in the non-display region BB and is used for being electrically connected with a control chip. The control chip region 1 may be provided with a plurality of first terminals. The control chip region 1 may be electrically connected with the control chip through the plurality of first terminals.

The bonding region 2 is located in the non-display region BB and at a side of the control chip region 1, and is used for being electrically connected with a circuit board. For example, as shown in FIG. 3, the bonding region 2 is on a right side of the control chip region 1. The bonding region 2 has a plurality of second terminals, and the bonding region 2 may be electrically connected with the circuit board through the plurality of second terminals.

A first electrostatic protection pad 31 is in the non-display region BB, and the first electrostatic protection pad 31 and the bonding region 2 are at different sides of the control chip region 1. For example, as shown in FIG. 3, the bonding region 2 is on the right side of the control chip region 1, and the first electrostatic protection pad 31 is on a left side of the control chip region 1.

A ground wire is located in the non-display region BB and includes a first ground wire part E1E4. One end of the first electrostatic protection pad 31 is electrically connected with a terminal (i.e., a second terminal) included in the bonding region 2 through the first ground wire part E1E4 surrounding the display region AA.

In embodiments of the present disclosure, for the first electrostatic protection pad 31 at the side different from the bonding region 2, the first electrostatic protection pad 31 is electrically connected with the terminal (i.e., the second terminal) included in the bonding region 2 at the other side of the control chip region 1 through the first ground wire part E1E4 surrounding the display region AA. When a circuit board 20 at a side where the first electrostatic protection pad 31 is located is removed, the first electrostatic protection pads 31 on the side can still be connected with a circuit board 20 on the other side of the control chip region 1, and the first electrostatic protection pad 31 on the side can still play an electrostatic protection role. The enhancement effect of the first electrostatic protection pad 31 on the electrostatic shielding effect is not weakened, solving the problem that the array substrate in the related art is easily damaged by static electricity when the bonding region at a side of the array substrate is removed.

In a possible embodiment, as shown in FIG. 3 and FIG. 4A, the array substrate further includes a second ground wire part E2E5. The other end of the first electrostatic protection pad 31 is electrically connected with a terminal (i.e., a first terminal) included in the control chip region 1 through the second ground wire part E2E5. In embodiments of the present disclosure, the other end of the first electrostatic protection pad 31 is also electrically connected with a terminal included in the control chip region 1 through the second ground wire part E2E5, to enhance the conduction effect of removing the static electricity generated at a side of the circuit board.

In a possible embodiment, as shown in FIG. 3 and FIG. 4A, the array substrate further includes a second electrostatic protection pad 32. The ground wire further includes a third ground wire part E4E7. The second electrostatic protection pad 32 is electrically connected with a terminal included in the bonding region 2 through the third ground wire part E4E7. In embodiments of the present disclosure, the second electrostatic protection pad 32 at a side of the circuit board 20 is not removed, and can be electrically connected with the terminal included in an adjacent bonding region 2, to have a better electrostatic conduction effect.

In a possible embodiment, as shown in FIG. 3 and FIG. 4A, the array substrate further includes a fourth ground wire part E3E6. The control chip region 1 is electrically connected with the bonding region 2 through the fourth ground wire part E3E6.

In a possible embodiment, as shown in FIG. 3 and FIG. 4A, the array substrate further includes a fifth ground wire part E5E6. The fifth ground wire part E5E6 is at a side of the control chip region 1 away from the display region AA. One end of the fifth ground wire part is electrically connected with a terminal included at one end of the control chip region 1, and the other end of the fifth ground wire part is electrically connected with a terminal included at the other end of the control chip region 1. In embodiments of the present disclosure, the side of the control chip region 1 away from the display region AA is further provided with the fifth ground wire part E5E6, to make antistatic ability better, and have the advantage of high performance.

In a possible embodiment, as shown in FIG. 4B, FIG. 4B may be a first enlarged schematic view at a dotted coil S1 in FIG. 4A. The control chip region 1 may include a plurality of first terminals P1. The control chip may be electrically connected with the first terminals P1 by means of conductive adhesive (such as anisotropic conductive adhesive ACF) or welding. The plurality of first terminals P1 may include a plurality of first lead-in terminals P11 sequentially arranged along a first direction X, and a plurality of second lead-out terminals P12 sequentially arranged along the first direction X. The first lead-in terminal P11 may be electrically connected with the second terminal P2 in the bonding region 2 in FIG. 4E through a signal line. The second lead-out terminals P12 may be electrically connected with a plurality of data lines included in a display panel. A display region of the display panel may include scan lines extending along rows and data lines extending along columns. An intersection of the scan line and the data line defines a sub-pixel unit. One end of the fifth ground wire part E5E6 (the left end of the fifth ground wire part E5E6 in FIG. 4A) is electrically connected with a first lead-in terminal P11 (a ground terminal among the first lead-in terminals P11) included in one end of the control chip region 1 (the left end of the control chip region 1 in FIG. 4A). The other end of the fifth ground wire part E5E6 (the right end of the fifth ground wire part E5E6 in FIG. 4A) is electrically connected with a first lead-in terminal P11 (a ground terminal among the first lead-in terminals P11) included in the other end of the control chip region 1 (the right end of the control chip region 1 in FIG. 4A). Optionally, a plurality of first lead-in terminals P11 are provided. The ground terminal (electrically connected with a ground terminal of the bonding region) may be one of terminals near both ends of a plurality of first lead-in terminals arranged in sequence. As shown in FIG. 4E, FIG. 4E is an enlarged schematic view at a dotted coil S2 in FIG. 4A. The fourth ground wire part E3E6 led out from the first lead-in terminal P11 at the right end of the control chip region 1 is connected with a second terminal P2 of the bonding region 2 (a ground terminal in the second terminal P2, optionally, the ground terminal included in the second terminal P2 may be one of terminals near both ends of a plurality of second terminals arranged in sequence). The second terminal P2 of the bonding region 2 may be electrically connected with the circuit board 20 by means of conductive adhesive (such as anisotropic conductive adhesive ACF) or welding. The ground terminal in the second terminal P2 and a ground signal line in the circuit board 20 are electrically connected.

In another possible embodiment, as shown in FIG. 4C, the fifth ground wire part E5E6 may not be electrically connected with a terminal included in the control chip region 1, that is, may not be connected with the control chip region 1. The other end (the right end in FIG. 4A) of the second electrostatic protection pad 32 is directly electrically connected with a terminal included in the bonding region 2.

In another possible embodiment, as shown in FIG. 4D, when the fifth ground wire part E5E6 is not electrically connected with a terminal included in the control chip region 1, the fifth ground wire part E5E6 may be wired in a gap region between the first lead-in terminals P11 and the second lead-out terminals P12 in the control chip region 1. Compared to a case where the fifth ground wire part E5E6 is wired at a side of the control chip region 1 away from the display region AA as shown in FIGS. 4B and 4C, the fifth ground wire part E5E6 in embodiments of the present disclosure is wired in a gap region between the first lead-in terminals P11 and the second lead-out terminals P12 in the control chip region 1. A width of a bezel of the display panel can be further reduced, which is beneficial to realization of the narrow bezel of the display panel.

In a possible embodiment, as shown in FIGS. 3 and 4A, a length of the fifth ground wire part E5E6 is substantially equal to a length of the control chip region 1.

In a possible embodiment, as shown in FIGS. 3 and 4A, at least a part of at least one of the first ground wire part E1E4, the second ground wire part E2E5, the third ground wire part E4E7, the fourth ground wire part E3E6, or the fifth ground wire part E5E6 is arc-shaped.

In a possible embodiment, as shown in FIGS. 3 and 4A, the control chip region 1 extends along a first direction X, and has a first symmetry axis k perpendicular to the first direction X. The first electrostatic protection pad 31 and the second electrostatic protection pad 32 are symmetrical with respect to the first symmetry axis k. The first electrostatic protection pad 31 and the second electrostatic protection pad 32 may be strip-shaped. An extension line of an outer edge of the first electrostatic protection pad 31 along a length direction and an extension line of an outer edge of the second electrostatic protection pad 32 along length direction may not coincide with each other.

In a possible embodiment, an outer contour shape of the array substrate is circular, elliptical, hexagonal, or octagonal. Alternatively, polygons of other numbers of sides are possible, for example, a triangle, a quadrilateral, a pentagon, a heptagon, a nonagon, a decagon, a dodecagon, a hexadecagon, or an octadecagon, etc.

In a possible embodiment, see FIG. 3 or FIG. 4A, the first electrostatic protection pad 31 and the second electrostatic protection pad 32 are arranged in a splayed shape.

Based on the same inventive concept, embodiments of the present disclosure further provide a display panel, as shown in FIG. 5, includes an array substrate 4 according to embodiments of the disclosure, an opposite substrate 5 opposite to the array substrate 4, a control chip 10 in the control chip region 1, and a circuit board 20 in the bonding region 2. The control chip 10 may be a source control chip (Source IC), and provides data signals for the display panel.

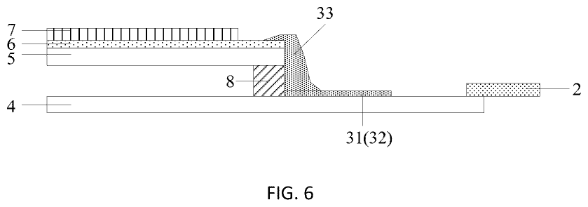

In a possible embodiment, as shown in FIG. 6, FIG. 6 may be a cross-sectional view of a dotted line of FIG. 5 at the first electrostatic protection pad 31, and the display panel further includes a conductive adhesive 33 and a frame sealing adhesive 8. Part of the conductive adhesive 33 covers a peripheral part of the opposite substrate 5, part of the conductive adhesive covers a side edge of the frame sealing adhesive 8, and part of the conductive adhesive extends to the first electrostatic protection pad 31 and/or the second electrostatic protection pad 32 of the array substrate 4 along a side edge of the opposite substrate 5. As such, static electricity generated by the opposite substrate 5 can be conducted to the first electrostatic protection pad 31 and/or the second electrostatic protection pad of the array substrate through the conductive adhesive 33, and further conducted to the ground terminal of the circuit board 20 through the first electrostatic protection pad 31 and/or the second electrostatic protection pad 32, to realize electrostatic discharge. The conductive adhesive 33 may include a silver paste.

In a possible embodiment, as shown in FIG. 6, a conductive layer 6 is at a side of the opposite substrate 5 away from the array substrate 4. The conductive adhesive 33 is lapped with the conductive layer 6 of the opposite substrate 5. The conductive layer 6 may be a transparent conductive layer. A material of the conductive layer 6 may include indium tin oxide and/or aluminum-doped zinc oxide (AZO). Optionally, the conductive layer may be a whole layer. A Polarizer 7 is on a side of the conductive layer away from the array substrate 4. It should be noted that, in the present disclosure, optionally, the polarizer 7 may have a conductive function. When the polarizer 7 has a conductive function, the conductive adhesive can be directly lapped on the polarizer (namely, the conductive adhesive is lapped on a side of the polarizer away from the substrate to realize the effect of leading out static electricity. In this case, the conductive layer 6 can be omitted to reduce a thickness of the display apparatus.

It should be noted that, as shown in FIG. 6, the first electrostatic protection pad 31 and/or the second electrostatic protection pad 32 may be silver glue dot contact for being electrically connected with the conductive layer 6 on a side of the opposite substrate 5, to conduct static electricity away from a side of the opposite substrate 5. In another possible embodiment, the first electrostatic protection pad 31 and/or the second electrostatic protection pad 32 may also be used as a conductive structure arranged on a side of the array substrate 4 (not used for connecting with the silver glue dot), and is used for electrically connecting ground wires at two sides of the control chip 10.

In a possible embodiment, as shown in FIGS. 3, 4A, 5, and 6, the control chip region 1, the bonding region 2, and the ground wire may all be located on the array substrate 4.

In a possible embodiment, as shown in FIGS. 3, 4A, and 5, the array substrate 4 includes a first region BB1 overlapped with the opposite substrate 5, and a second region BB2 extended from the first region BB1. The control chip region 1, the bonding region 2, and the ground wire are all in the second region BB2 of the array substrate. Referring to FIG. 3, FIG. 4A and FIG. 5, C1 may be a projection line of an outer edge of the opposite substrate 5 on the array substrate 4. C2 may be an outer edge of the array substrate 4. A region between C1 and C2 may be the second region BB2. That is, a region where the array substrate 4 protrudes outward with respect to the opposite substrate 5 serves as the second region BB2.

Based on the same inventive concept, embodiments of the present disclosure further provide a display apparatus. The display apparatus includes the display panel according to embodiments of the present disclosure.

Beneficial effects of embodiments of the present disclosure are as follows: in embodiments of the present disclosure, for the first electrostatic protection pad 31 at the side different from the bonding region 2, the first electrostatic protection pad 31 is electrically connected with the terminal (i.e., the second terminal) included in the bonding region 2 at the other side of the control chip region 1 through the first ground wire part E1E4 surrounding the display region AA. When a circuit board 20 at a side where the first electrostatic protection pad 31 is located is removed, the first electrostatic protection pads 31 on the side can still be connected with a circuit board 20 on the other side of the control chip region 1, and the first electrostatic protection pad 31 on the side can still play an electrostatic protection role. The enhancement effect of the first electrostatic protection pad 31 on the electrostatic shielding effect is not weakened, solving the problem that the array substrate in the related art is easily damaged by static electricity when the bonding region at a side of the array substrate is removed.

Based on the same inventive concept, embodiments of the present disclosure further provide a display apparatus. The display apparatus includes the display panel according to embodiments of the disclosure. For implementations of the display apparatus, reference may be made to embodiments of the display panel, and repetition thereof is omitted.

In a specific implementation, in embodiments of the present disclosure, the display apparatus can be a round, oval, hexagonal or octagonal and other special-shaped wearable products. Other essential components of the display apparatus are as will be understood by those skilled in the art, and are not intended to be exhaustive or to be limiting of the present disclosure.

Although embodiments of the present disclosure have been described, those skilled in the art may otherwise make various modifications and variations to these embodiments once they are aware of the basic inventive concept. Therefore, the claims intend to include embodiments as well as all these modifications and variations falling within the scope of the present disclosure.

Apparently, those skilled in the art can make various modifications and variations to embodiments of the present disclosure without departing from the spirit and scope of embodiments of the present disclosure. In this way, if the modifications and variations of embodiments of the present disclosure fall within the scope of the claims of the present disclosure and their equivalent technologies, the present disclosure is also intended to include these modifications and variations.

1. An array substrate, having a display region and a non-display region at a
periphery of the display region, wherein the array substrate comprises:
a control chip region, located in the non-display region and used for being electrically connected with a control chip;
a bonding region, located in the non-display region and at a side of the control chip region and used for being electrically connected with a circuit board;
a first electrostatic protection pad in the non-display region, wherein the first electrostatic protection pad and the bonding region are at different sides of the control chip region; and
a ground wire, located in the non-display region and comprising a first ground wire part, wherein one end of the first electrostatic protection pad is electrically connected with a terminal comprised in the bonding region through the first ground wire part surrounding the display region.

2. The array substrate according to claim 1, wherein the ground wire further comprises a second ground wire part; the other end of the first electrostatic protection pad is electrically connected with a terminal comprised in the control chip region through the second ground wire part.

3. The array substrate according to claim 1, wherein the array substrate further comprises a second electrostatic protection pad; the ground wire further comprises a third ground wire part;
the second electrostatic protection pad is electrically connected with a terminal comprised in the bonding region through the third ground wire part.

4. The array substrate according to claim 1, wherein the ground wire further comprises a fourth ground wire part; the control chip region is electrically connected with the bonding region through the fourth ground wire part.

5. The array substrate according to claim 1, wherein the array substrate further comprises a fifth ground wire part; the fifth ground wire part is at a side of the control chip region away from the display region, one end of the fifth ground wire part is electrically connected with a terminal comprised at one end of the control chip region, and the other end of the fifth ground wire part is electrically connected with a terminal comprised at the other end of the control chip region.

6. The array substrate according to claim 5, wherein a length of the fifth ground wire part is substantially equal to a length of the control chip region.

7. The array substrate according to claim 5, wherein at least a part of at least one of the first ground wire part, a second ground wire part, a third ground wire part, a fourth ground wire part, or a fifth ground wire part is arc-shaped.

8. The array substrate according to claim 1, wherein the control chip region extends along a first direction, and has a first symmetry axis perpendicular to the first direction;
the first electrostatic protection pad and a second electrostatic protection pad are symmetrical with respect to the first symmetry axis.

9. The array substrate according to claim 1, wherein an outer contour of the array substrate is circular, elliptical, hexagonal or octagonal.

10. The array substrate according to claim 9, wherein the first electrostatic protection pad and a second electrostatic protection pad are distributed in a splayed shape.

11. A display panel, comprising the array substrate of claim 1, an opposite substrate opposite to the array substrate, the control chip in the control chip region, and the circuit board in the bonding region.

12. The display panel according to claim 11, wherein the display panel further comprises: a conductive adhesive; part of the conductive adhesive covers a peripheral part of the opposite substrate, and part of the conductive adhesive extends to the first electrostatic protection pad and/or a second electrostatic protection pad of the array substrate along a side edge of the opposite substrate.

13. The display panel according to claim 12, wherein a conductive layer is at a side of the opposite substrate away from the array substrate, and the conductive adhesive is lapped with the conductive layer.

14. The display panel according to claim 11, wherein the array substrate comprises a first region overlapped with the opposite substrate, and a second region extending from the first region;
the control chip region, the bonding region, and the ground wire are all in the second region of the array substrate.

15. A display apparatus, comprising the display panel according to claim 11.
